(19) United States
(12) Patent Application Publication
(10) Pub. No.: US 2010/0317173 A1
(43) Pub. Date: Dec. 16, 2010

(54) Dicing Tape and Process for Manufacturing a Semiconductor Device

(75) Inventor: Michio Kanai, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: LINTEC CORPORATION, Tokyo (JP)

(21) Appl. No.: 12/525,892

(22) PCT Filed: Jan. 29, 2008
(86) PCT No.: PCT/JP2008/051275

§ 371 Date: Aug. 5, 2009

(30) Foreign Application Priority Data
Feb. 6, 2007 (JP) 2007-027039

(51) Int. Cl. H01L 21/78; B32B 27/38

(52) U.S. Cl. 438/464; 428/355 EP; 257/E21.599

(57) ABSTRACT

A process for manufacturing a semiconductor device through an inlined operation includes the step of attaching a dicing tape to the ground surface immediately after the completion of the grinding of the reverse side. The dicing tape includes a base material and, undetachably laminated thereon, an adhesive layer that includes an adhesive component and an epoxy group-containing compound being free but that does not contain any hardener for epoxy resins.

### TECHNICAL FIELD

The present invention relates to a dicing tape and a process for manufacturing a semiconductor device. More particularly, the present invention relates to a dicing tape that in the employment of a so-called inlined process, realizes a reduction of pickup failures in the chip pickup step, and also relates to a process for manufacturing a semiconductor device with the use of the dicing tape.

### BACKGROUND ART

In recent years, in accordance with the growing popularity of IC cards, further reduction of the thickness thereof is demanded. Accordingly, it is needed to reduce the thickness of semiconductor chips having been about 350 μm to 50 to 100 μm or less. The reverse side of a wafer is ground after attaching a surface protective sheet to the circuit side thereof so as to ensure protection of the circuit surface and fixing of the wafer. The grinding is followed by various steps including dicing, pickup, die bonding and resin sealing. As a result, a semiconductor device is obtained.

In the dicing of a semiconductor wafer into chips, a dicing tape is attached to the reverse side (ground side) of the semiconductor wafer, and the wafer is diced while holding the wafer on the dicing tape. Various dicing tapes are commercially available. In particular, an ultraviolet-curable adhesive tape known as a UV tape is preferably employed. The UV tape has such a property that the adhesive layer thereof is cured by irradiation with ultraviolet rays to thereby have its adhesive strength lost or sharply decreased. Therefore, the UV tape is capable of fixing the wafer with a satisfactory adhesive strength in the stage of wafer dicing, but after the completion of the dicing, it allows easy pickup of the chips through ultraviolet curing of the adhesive layer thereof.

For attaching the dicing tape, the wafer whose reverse side grinding has been completed is transferred to a dicing tape attaching unit (mounter). In the transfer to the mounter, the wafer is stored in a storage unit known as a wafer cassette.

However, when the wafer is ground to an extreme thinness, the wafer per se would lose its self supporting capability, and breakage thereof by its own weight would be likely. Therefore, it is difficult to store the wafer having been ground to an extreme thinness per se in the wafer cassette.

In order to impart a supporting capability to the semiconductor wafer whose strength has been lowered, it is proposed to adopt a process inlining, namely, attaching a dicing tape to the ground surface immediately after the completion of the reverse side grinding and thereafter conducting the transfer to the dicing operation. For example, the patent document 1 describes an example of such an inlined process. In this process, even a wafer, which is ground to an extreme thinness to thereby have its strength lowered, is reinforced from the reverse side thereof by the dicing tape. As a result, the supporting capability is enhanced to thereby allow the above transfer using the wafer cassette.

However, the unforeseen problem that an increase of chip pickup failure is caused as a result of such an inlining has occurred. This is a problem that the chip pickup becomes difficult due to an increase of adhesive strength between the chip reverse side and the adhesive layer. In the use of the UV tape as the dicing tape as well, the pickup failures have increased.

As a cause thereof, an insufficiency of the formation of an oxide layer on the reverse side of the wafer is pointed out in the patent document 2. That is, the reverse side of the wafer immediately after the grinding of the reverse side is in an activated state due to the removal of the oxide layer. When the dicing tape is attached to the reverse side in the activated state, the wafer and the adhesive layer excessively adhere to each other because of a high affinity between the reverse side and the adhesive layer. It is assumed that the excessive adherence would cause pickup failures. In the patent document 2, in order to resolve this problem, it is proposed to form an oxide layer on the reverse side of the wafer after the completion of the grinding of the reverse side to thereby decrease the activity of the reverse side of the wafer.

However, in the method of the patent document 2, not only is a new step for forming an oxide layer added to thereby render the process cumbersome, but also a unit for forming an oxide layer becomes necessary.

Further, in recent years, the pickup speed is being increased for productivity enhancement. That is, in the chip pickup involving a chip detachment through thrusting each chip by means of a thrust pin and retaining the chip by means of a suction collet, the thrusting speed of the thrust pin is being increased. As a result, the detachment of the chip from the dicing tape has become insufficient to thereby cause the chip pickup to be difficult or bring about a frequent occurrence of chip breakage.

Patent document 1: JP 2002-343756 A

Patent document 2: JP 2005-72140 A

### DISCLOSURE OF THE INVENTION

### Problem to be Solved by the Invention

Therefore, in the above-mentioned process for manufacturing a semiconductor device through an inlined operation including attaching a dicing tape to the ground surface immediately after the completion of the grinding of the reverse side, it is required to resolve the pickup failures by convenient means. The present invention has been made in view of the above prior art. It is an object of the present invention to study the composition of an adhesive used in the dicing tape and accordingly satisfy the above requirement.

### Means for Solving the Problem

The gist of the present invention having been made for the resolution of the above problem is as follows.

[1] A dicing tape comprising a base material and, undetachably laminated thereon, an adhesive layer that comprises an epoxy group-containing compound being free and an adhesive component but does not contain any hardener for epoxy resins.
[2] The dicing tape according to the above item 1, wherein the base material on its side of the adhesive layer has a surface tension of 45 mN/m or greater.
[3] The dicing tape according to the above item 1, wherein the adhesive component is energy ray-curable.
[4] The dicing tape according to the above item 2, wherein the adhesive component is energy ray-curable.
[5] A process for manufacturing a semiconductor device, comprising the steps of:

grinding the reverse side of a semiconductor wafer provided on its obverse side with a circuit,

attaching the dicing tape of any one of the above items 1 to 4 to the reverse side of the semiconductor wafer and dicing the semiconductor wafer into semiconductor chips, and

picking up the semiconductor chips.

### EFFECT OF THE INVENTION

According to the present invention, by virtue of the use of a dicing tape having an adhesive layer of a special composition, any excessive adhesion of the adhesive layer to the wafer surface immediately after the grinding of the reverse side can be avoided to thereby realize a secure pickup of chips after the dicing.

### BEST MODE FOR CARRYING OUT THE INVENTION

The present invention will be described in greater detail below. First, the dicing tape of the present invention will be described.

The dicing tape of the present invention comprises a base material and, undetachably laminated thereon, an adhesive layer. Herein, the undetachability means that under ordinary conditions of use, even when the attaching and detaching of the dicing tape are carried out, the adhesive layer is not transferred to the adherend and is united with the base material while allowing detachment from the adherend.

The dicing tape of the present invention may have unlimited configurations including the forms of a tape and a label.

The base material, although not particularly limited, is suitable to employ one excelling in water resistance and thermal stability. As such, use can be made of films of polyethylene terephthalate, polyethylene naphthalate, low-density polyethylene (LDPE), linear low-density polyethylene (LLDPE), ethylene-propylene copolymer, polypropylene, polybutene, polybutadiene, polymethylpentene, ethylene-vinyl acetate copolymer, ethylene-(meth)acrylic acid copolymer, ethylene-methyl (meth)acrylate copolymer, ethylene-ethyl (meth)acrylate copolymer, polyvinyl chloride, vinyl chloride-vinyl acetate copolymer, ethylene-vinyl chloride-vinyl acetate copolymer, polyurethane films, polyamide films, polyimide films, ionomers and the like. These synthetic resin films can be used in the form of a laminate of two or more members thereof or in other combination. Further, these films may be colored, printed or otherwise processed before use. Still further, these films may be those obtained by sheeting a thermoplastic resin through extrusion forming, or those obtained by forming a curable resin into a thin film by given means and curing the film to thereby accomplish sheeting.

The thickness of the base material, although not particularly limited, is generally in the range of 5 to 500 μm, preferably 10 to 300 μm. In order to increase the adhesion with the adhesive layer, the base material on its side in contact with the adhesive layer may be subjected to corona treatment or may be provided with another layer such as a primer. The base material having high adhesion with the adhesive layer generally exhibits a high surface tension value. The surface tension of the base material for use in the present invention on its side close to the adhesive layer is preferably 45 mN/m or greater, preferably in the range of 50 to 80 mN/m.

In the execution of the process for manufacturing a semiconductor device according to the present invention, at the stage of chip pickup, the dicing tape may be expanded so as to allow an appropriate spacing between chips. If this is done, as the base material, preferred use is made of any of ethylene-vinyl acetate copolymer, ethylene-(meth)acrylic acid copolymer, ethylene-methyl (meth)acrylate copolymer, ethylene-ethyl (meth)acrylate copolymer, polyvinyl chloride, vinyl chloride-vinyl acetate copolymer, ethylene-vinyl chloride-vinyl acetate copolymer and the like all excelling in elongation.

When an adhesive of the type being cured by energy rays such as ultraviolet rays, is used as an adhesive component, a base material being transparent in ultraviolet rays or the like is employed.

The adhesive layer provided on the base material contains an adhesive component and an epoxy group-containing compound but does not contain any hardener for epoxy resins.

With respect to the adhesive component, the type thereof is not particularly limited as long as an appropriate removability is ensured. The adhesive component may comprise any of widely used adhesives such as those based on a rubber, acrylic, silicone, urethane, vinyl ether, etc. Of these, in particular, an acrylic adhesive is preferably used.

Examples of the acrylic adhesive include one composed mainly of a (meth)acrylic ester copolymer obtained from a (meth)acrylic ester monomer and a functional group-containing monomer as main raw components. As the (meth)acrylic ester monomer, use may be made of methyl (meth)acrylate, ethyl (meth)acrylate, propyl (meth)acrylate, butyl (meth)acrylate, hexyl (meth)acrylate, octyl (meth)acrylate, 2-ethylhexyl (meth)acrylate, isooctyl (meth)acrylate or the like. Further, as the (meth)acrylic ester monomer, use may be made of an alkyl ester having an alicyclic group or aromatic group, such as a cycloalkyl (meth)acrylate or benzyl (meth)acrylate. These monomers may be used either individually or in combination of two or more kinds.

As the functional group-containing monomer, use is made of a monomer having in its molecule a functional group such as a hydroxyl group, a carboxyl group, an amino group, a substituted amino group and an epoxy group. Preferably, a hydroxyl group-containing unsaturated compound or a carboxyl group-containing unsaturated compound is employed. Specific examples of such a functional group-containing monomers include a hydroxyalkyl (meth)acrylate such as 2-hydroxyethyl (meth)acrylate, 2-hydroxypropyl (meth)acrylate and 3-hydroxypropyl (meth)acrylate; a monoalkylaminoalkyl (meth)acrylate such as monomethylaminoethyl (meth)acrylate and monoethylaminoethyl (meth)acrylate; a carboxyl group-containing monomer such as acrylic acid, methacrylic acid, crotonic acid, maleic acid, itaconic acid and citraconic acid; and acetoacetoxymethyl (meth)acrylate. These monomers may be used either individually or in combination of two or more kinds.

The (meth)acrylic ester copolymer may contain a copolymerizable monomer other than the (meth)acrylic ester monomer and functional group-containing monomer. Examples of the other copolymerizable monomer include acrylonitrile, acrylamide and a vinyl ester such as vinyl acetate and vinyl butyrate.

As the functional group, such as a carboxyl group and an amino group, may react with an epoxy group to thereby consume the epoxy group-containing compound, when a monomer having such a functional group is used as a raw material of the (meth) acrylic ester copolymer, it is preferred to lower the ratio thereof.

The molecular weight of the (meth) acrylic ester copolymer is preferably 100,000 or greater, more preferably in the range of 150,000 to 1,000,000. The glass transition temperature of the acrylic adhesive is generally 20° C. or below, preferably in the range of about −70° to 0° C. The acrylic adhesive is adhesive at ordinary temperature (23° C.).

It is preferred for the adhesive layer to be formed from a composition containing an energy ray-curable adhesive which when irradiated with energy rays, such as ultraviolet rays, is cured to thereby become removable. The energy ray-curable adhesive is generally composed mainly of the above (meth) acrylic ester copolymer and an energy ray-polymerizable compound.

For example, a low molecular weight compound having in its molecule at least two photopolymerizable carbon-carbon double bonds that is convertible to a three-dimensional network by photoirradiation is widely used as the energy ray-polymerizable compound. In particular, as such, use is made of trimethylolpropane triacrylate, tetramethylolmethane tetraacrylate, pentaerythritol triacrylate, pentaerythritol tetraacrylate, dipentaerythritol monohydroxypentaacrylate, dipentaerythritol hexaacrylate, or 1,4-butyleneglycol diacrylate, 1,6-hexanediol diacrylate, polyethylene glycol diacrylate, oligoester acrylate, urethane acrylate or the like.

With respect to the mixing ratio between the (meth) acrylic ester copolymer and the energy ray-polymerizable compound in the energy ray-curable adhesive layer, it is preferred to use 10 to 1000 parts by weight, especially 20 to 500 parts by weight and more especially 50 to 200 parts by weight of the energy ray-polymerizable compound per 100 parts by weight of the (meth) acrylic ester copolymer. If this is implemented, the obtained adhesive sheet exhibits a high adhesive strength in the initial stage and a sharp decrease of adhesive strength after irradiation with energy rays. Accordingly, while a wafer and chips can be securely held at the stage of the dicing, the adhesive strength is sharply decreased by energy ray irradiation at the stage of pickup to thereby allow secure pickup of the chips.

The energy ray-curable adhesive may be produced from an energy ray-curable copolymer having an energy ray-polymerizable group at its side chain. This energy ray-curable copolymer is adhesive and energy ray-curable. Examples of the energy ray-curable copolymer having an energy ray polymerizable group at its side chain include one resulting from providing any of the above-mentioned (meth)acrylic ester copolymers with a side chain having an energy ray-polymerizable carbon-carbon double bond. For example, this copolymer can be obtained by reacting a compound containing not only a substituent capable of reacting with the functional group of the (meth)acrylic ester copolymer but also an energy ray polymerizable carbon to carbon double bond with a (meth)acrylic ester copolymer.

When ultraviolet rays are employed as the energy rays, it is preferred to mix a photopolymerization initiator into the adhesive layer. Examples of the photopolymerization initiator include benzophenone, acetophenone, benzoin, benzoin methyl ether, benzoin ethyl ether, benzoin isopropyl ether, benzoin isobutyl ether, benzoin benzoic acid, methyl benzoin benzoate, benzoin dimethylketal, 2,4-diethylthioxanthone, α-hydroxycyclohexyl phenyl ketone, benzyldiphenyl sulfide, tetramethyl thiuram monosulfide, azobisisobutyronitrile, benzil, dibenzyl, diacetyl, β-chloranthraquinone and 2,4,6-trimethylbenzoyldiphenylphosphine oxide.

The ratio of photopolymerization initiator added is variable depending on the ratio of the energy ray-polymerizable compound and the energy ray-polymerizable group in the adhesive layer or the reactivity thereof. However, the photopolymerization initiator is generally used in an amount of 0.1 to 10 parts by mass, preferably 0.5 to 5 parts by mass per 100 parts by mass of the energy ray-curable adhesive (the energy ray-curable copolymer).

Further, the adhesive layer contains an epoxy group-containing compound.

Examples of the epoxy group-containing compound for use in the present invention include a compound having at least one epoxy group in its molecule that can be thermally cured with the use of a hardener for epoxy resins. Examples thereof include epoxy resin of bisphenol-A, bisphenol-F, bisphenol-S, biphenyl, phenol novolac or cresol novolac.

It is preferred for the molecular weight of the epoxy group-containing compound to be relatively low. The molecular weight is generally in the range of 300 to 2000, preferably 350 to 1000. When the molecular weight falls within this range, the transfer of the epoxy group-containing compound, which is present in the interface between the adhesive and the chips after attachment, to the chip side is facilitated to thereby be effective in lowering the chip pickup strength.

It is preferred for the epoxy group-containing compound to be inreactive with the (meth) acrylic ester copolymer. Thus, preferably, the epoxy group-containing compound does not have any functional group capable of activating the epoxy group, such as an amino group.

The ratio of epoxy group-containing compound added depends on the type of the epoxy group-containing compound and cannot be flatly determined. However, generally, the epoxy group-containing compound is used in an amount of about 0.5 to 50 parts by mass, preferably 2.5 to 25 parts by mass per 100 parts by mass of the total of the constituents of the adhesive layer.

The above-mentioned addition ratio of the epoxy group-containing compound refers to the composition at the time of preparation, and the epoxy group-containing compound is contained in the state of being free in the adhesive layer. That is, the adhesive layer comprises an “epoxy group-containing compound being free.” Herein, the state of being free refers to a state such that there is substantially no reaction between the epoxy group-containing compound and the (meth) acrylic ester copolymer and that the epoxy group-containing compound is not incorporated in the gel component matrix of the (meth) acrylic ester copolymer. In particular, the presence or absence of any unreacted epoxy group-containing compound can be judged by titration of the epoxy group of the sol component of the adhesive layer. In the present invention, evaluation is made by an “epoxy index” referring to 1000 times the inverse number of an epoxy equivalent. The “epoxy index” refers to the amount of epoxy groups per kg of a sample. In the present invention, the amount of epoxy groups in the sol contents of the adhesive is measured, and this amount is reduced to a value per kg of the entirety (including not only sol contents but also gel contents) of the adhesive. The value of the epoxy index is preferably 0.05 eq/kg or greater, more preferably in the range of 0.1 to 2.0 eq/kg. These values of the “epoxy index” are those determined by the measuring method employed in the Examples to be described later.

Therefore, the adhesive layer for use in the present invention contains substantially no substance (hardener for epoxy resins) having the activity of polymerizing the above epoxy group-containing compound. If a hardener for epoxy resins is contained in the adhesive layer, the epoxy group-containing compound might be cured after the attachment of the semiconductor wafer to thereby bring about bonding between the semiconductor wafer and the adhesive layer, which bonding would cause pickup failures. Examples of the hardener for epoxy resins substantially not contained include an organic acid, an acid anhydride, a phenolic resin, a urea resin and a polyamide.

As apparent from the above, the adhesive layer for use in the present invention consists essentially of the adhesive component and the epoxy group-containing compound. As aforementioned, the adhesive component may be an energy ray-curable adhesive component.

In the adhesive layer for use in the present invention, components other than the adhesive component and the epoxy group-containing compound may be mixed unless the gist of the present invention is adversely affecting. Examples of the other components include not only the aforementioned photopolymerization initiator but also a crosslinking agent (crosslinking agent for the adhesive component), an inorganic filler, a plasticizer, an antistatic agent, an antioxidant, an antiaging agent, a pigment and a dye.

As the crosslinking agent, use can be made of widely known substances such as a polyisocyanate compound, a polyaziridine compound and a chelate compound, or the like. As the polyisocyanate compound, use is made of toluoylene diisocyanate, diphenylmethane diisocyanate, hexamethylene diisocyanate, isophorone diisocyanate, any of adducts from these polyisocyanates and polyhydric alcohols, or the like. As the polyaziridine compound, use is made of tris-2,4,6-(1-aziridinyl)-1,3,5-triazine, tris[1-(2-methyl)aziridinyl]triphosphatriazine or the like. As the chelate compound, use is made of ethylacetoacetatoaluminum diisopropylate, aluminum tris(ethylacetoacetate) or the like. These may be used either individually or in a mixture.

The crosslinking agent is used in a ratio of generally 0.01 to 10 parts by mass, preferably 0.1 to 5 parts by mass and more preferably 0.5 to 3 parts by mass per 100 parts by mass of the adhesive component.

The thickness of the adhesive layer is not particularly limited. However, it is generally in the range of 1 to 100 μm, preferably 5 to 40 μm.

When an adherend, such as a semiconductor wafer, is attached to the above adhesive layer containing an unreacted epoxy group-containing compound, the epoxy group-containing compound contained in the adhesive layer would ooze out to thereby bring about the state of forming an oil film on the interface with the adherend. As a result, excessive adhesion of the adhesive layer to the adherend is avoided. Accordingly, even when the reverse side of the wafer is in the state of being activated immediately after the grinding, an appropriate detachability is attained. Therefore, chip pickup failures after the dicing is reduced.

A process for producing the dicing tape of the present invention is not particularly limited. The dicing tape may be produced by applying a composition, obtained by dissolving or dispersing the components as constituents of the adhesive layer in an appropriate solvent, onto a base material and drying the composition. Alternatively, the production may be carried out by superimposing the adhesive layer on a release film and transferring the layer to the base material. For the purpose of protecting the adhesive layer, the release film may be laminated on the surface of the adhesive layer before the use of the dicing tape.

The process for manufacturing a semiconductor device with the use of the dicing tape according to the present invention will be described below.

In the process for manufacturing a semiconductor device according to the present invention, first, the reverse side of a semiconductor wafer provided on its obverse side with a circuit is ground. The semiconductor wafer may be a silicon wafer, or a compound semiconductor wafer of gallium arsenide or the like.

The wafer surface can be provided on its obverse side with a circuit by various methods including widely employed conventional techniques such as an etching technique and a liftoff technique. A predetermined circuit is formed in the stage of semiconductor wafer circuit formation. The pre-grinding thickness of this wafer is not particularly limited. However, it is generally in the range of about 650 to 750 μm.

In the stage of reverse side grinding, in order to protect the surface circuit, it is preferred to attach a surface protective sheet to the circuit surface. As the surface protective sheet, any of various removable adhesive sheets finding applications in this kind of usage can be employed without any particular limitation.

The reverse side is ground by a conventional method using a grinder, a suction table for fixing the wafer, etc. The operation of reverse side grinding may be followed by a treatment for removing any fractured layer generated by the grinding.

The thickness of the wafer after the operation of reverse side grinding is not particularly limited. However, from the viewpoint of adaptability to an inline processing suitable for extremely thin working in conformity with the objective of the present invention, it is preferred that the thickness of the wafer finished by the reverse side grinding range from about 20 to 100 μm. From the viewpoint of applicability to ordinary processing as well, however, the regular thickness of finished wafer ranging from about 100 to 400 μm can be employed.

Subsequently, the dicing tape of the present invention is attached to the reverse side of the wafer. The dicing tape is generally attached by the use of an equipment called a mounter having a roller. However, the attachment is not limited to the use of the mounter.

As the dicing tape, the aforementioned ultraviolet-curable adhesive tape is especially preferably employed because it allows a decrease of pickup strength. In the use of the dicing tape of the present invention, when it is attached, the epoxy group-containing compound contained in the adhesive layer forms an oil film on the ground surface of the wafer, so that the interaction between the ground surface of the wafer and the adhesive is decreased. Accordingly, even if the wafer on its ground surface immediately after the grinding is in the state of being activated, excessive adhesion of the wafer with the adhesive layer can be avoided to thereby attain an appropriate detachability and realize a striking enhancement of pickup performance in the stage of pickup after the dicing.

Therefore, the present invention is especially preferably applied to the wafer that on its ground surface immediately after the dicing is in the state of being activated. That is, the effect of the present invention is strikingly manifest in the resolution of the problem of pickup failure in the process for manufacturing a semiconductor device with the use of an inline processing apparatus wherein a grinder is combined with a dicing tape attaching unit. Accordingly, in the present invention, even when the interval between the operation of wafer grinding and the operation of dicing tape attachment is only, for example, about 0.5 to 3 min, a desirable pickup performance can be attained.

The method of dicing a semiconductor wafer is not particularly limited. For example, processing wafer into chips is carried out by a publicly known method such as one in which a peripheral portion of the dicing tape is fixed by means of a ring frame in the stage of wafer dicing and thereafter a rotary round blade such as a dicer is applied. The surface protective sheet is detached at an appropriate stage after the attachment of the dicing tape.

The thus obtained chips are picked from the dicing tape. The chip pickup is generally performed by using a suction collet from the side of the circuit surface. Simultaneously with the suction by the collet, the chips may be thrust by means of a thrust pin from the side of the dicing tape. When an energy ray-curable adhesive tape is used as the dicing tape, the adhesive layer is preferably irradiated with energy rays before the chip pickup to thereby lower the adhesive strength thereof.

In the stage of pickup, when the detachment of the dicing tape in the vicinity of an apical portion of the sequence of motion of a thrust pin is satisfactory, the suction collet would be able to grasp the chips, thereby ensuring the pickup. However, in the semiconductor manufacturing site of recent years, the thrust speed in the pickup operation is often set at a high level with a view toward productivity enhancement. Accordingly, in the use of conventional dicing tapes, the adhesion between the dicing tape and the reverse side of chips would become excessive, so that the detachment of the chips in the vicinity of an apical portion of the sequence of motion of a thrust pin would be unsatisfactory. Therefore, even when the suction collet is close to each chip, chip grasping would be failed to thereby cause pickup failures.

In the present invention, an oil film of the epoxy group-containing compound is formed on the reverse side of a semiconductor wafer by the attachment of the dicing tape. This decreases the interaction between the reverse side of the wafer and the adhesive layer of the dicing tape, so that excessive adhesion between the wafer and the dicing tape can be avoided to thereby reduce pickup failures in the stage of chip pickup after the dicing.

After the pickup, the chips are subjected to the die bonding and resin sealing according to routine procedure, thereby obtaining a semiconductor device. Although an oil film of the epoxy group-containing compound is adhering onto the reverse side of the picked chips, in the final semiconductor device, the oil film unites with the epoxy resin employed in the die bonding or resin sealing and is cured together, so that no adverse effect by residues occurs.

### EXAMPLE

Hereinbelow, the present invention will be described with reference to the following Examples, which however in no way limit the scope of the present invention.

In the following Examples and Comparative Examples, the “pickup time” and “pickup strength” were evaluated by the following method.

A dummy wafer of silicon (125 mm diameter and 650 μm thickness) was ground to a thickness of 350 μm by the use of a grinder. Within 5 min after the completion of the grinding by the grinder, each of the dicing tapes of the Examples and Comparative Examples was adhered to the ground surface of the wafer. Subsequently, within 1 hr after the completion of the grinding, the wafer was diced into 10 mm×10 mm chip sizes. Then, within 6 hr after the dicing, the dicing tape was irradiated from its base material side with ultraviolet rays as energy rays. In the period of 12 to 24 hr after the irradiation with ultraviolet rays, chip pickup was carried out, and the pickup time (time for the detachment of each chip from the tape) and the pickup strength (maximum load applied on each thrust pin) were measured for evaluation of pickup performance.

For comparison, the pickup performance was also evaluated with respect to the wafer thought to have lost its activity due to the passage of 7 days after the grinding.

The conditions for each of the operations are as follows.

### (Grinding Step)

Grinder: model DFG840 manufactured by DISCO Corporation.

### (Dicing Tape Attaching Step)

Attaching unit: model RAD2500 m/8 manufactured by LINTEC Corporation, and

Ring frame: No. 2-6-1 manufactured by DISCO Corporation.

### (Dicing Step)

Dicing apparatus: model A-WD-4000B manufactured by TOKYO SEIMITSU CO. LTD.,

Blade: NBC-ZH2050 27HECC manufactured by DISCO Corporation, and

Depth of cutting: full cut (30 μm cutting in dicing tape).

### (Ultraviolet Irradiation Step)

Ultraviolet irradiator: model RAD2000 m/8 manufactured by LINTEC Corporation,

Illuminance: 330 mW/cm²,

Light intensity: 210 mJ/cm²,

(The illuminance and light intensity were measured with the use of UV METER UVPF-36 manufactured by EYE GRAPHICS CO. LTD.), and

Nitrogen purge: performed (flow rate 30 liters/min.).

### (Pickup Step)

No. of thrust pins: 4,

Pin location: vertex of 8 mm-side square,

Degree of expansion: ring frame 2 mm pull-down,

Height of pin thrust: 1.5 mm, and

Thrusting speed: 0.3 mm/sec.

### (Epoxy Index)

In each of the Examples and Comparative Examples, the “epoxy index” of the adhesive was measured by the indicator titration method in accordance with JIS K7236. An adhesive having been collected in the stage of dicing tape production while being in the state of not being superimposed on a base material and having been aged at room temperature for a week, as a sample, was subjected to the measurement. About 0.1 to 1.0 g of the adhesive for measurement was extracted by ethyl acetate as a solvent by means of a Soxhlet extractor, thereby obtaining a sol component. The titration for the epoxy index was performed in the solution obtained by evaporating the ethyl acetate solvent and dissolving the resultant sol component in about 50 ml of chloroform. The epoxy indices of Table 1 are equivalences per kg of the adhesive before the extraction.

### (Molecular Weight)

Measuring apparatus: HLC-8020, AS-8020, SD-8000, UV-8020 manufactured by Tosoh Corporation,

Column: TSK gel GMH,

Flow rate: 1.0 ml/sec.,

Solvent: THF (tetrahydrofuran),

Temperature: 35° to 40° C. (inlet: 35° C., oven: 40° C. and RI: 35° C.),

Amount of sample injected: 80 μl,

Sample concentration: 0.8 to 1.3% solid, and

Calibration curve: in terms of polystyrene.

### Example 1

The following energy ray-curable polymer was used as an energy ray-curable adhesive component.

Use was made of an energy ray-curable polymer obtained by reacting an acrylic polymer (butyl acrylate/methyl methacrylate/hydroxyethyl acrylate=65/20/15 (mass ratio), weight average molecular weight=about 50×10⁴) with 80% equivalent of methacryloyloxyethyl acrylate (16 parts by mass per 100 parts by mass of the acrylic polymer).

An adhesive composition was obtained by blending 100 parts by mass of the above energy ray-curable polymer with 3.5 parts by mass of photopolymerization initiator (Irgacure (registered trade name) 184 produced by Ciba Specialty Chemicals Corporation), 10 parts by mass of epoxy group-containing compound (Epiclon (registered trade name) EXA-4850-150, molecular weight about 900, produced by Dainippon Ink & Chemicals, Inc.) and 1.07 parts by mass of isocyanate compound (BHS-8515 produced by TOYO INK MFG. CO., LTD.). The blending ratios all refer to ratios in terms of solid contents.

The obtained adhesive composition was applied to a release film (SP-PET3811 (S) with a thickness of 38 μm produced by LINTEC Corporation) so that the coating amount after drying was 10 g/m². The adhesive composition was dried at 100° C. for 1 min. and superimposed on the corona treated surface of an ethylene-methacrylic acid copolymer film treated on its one side with corona (thickness 80 μm, surface tension on the corona treated surface 54 mN/m) as a base material. Thus, a dicing tape was obtained.

Using the obtained dicing tape, the “pickup time” and “pickup strength” were evaluated by the above-mentioned method. The results are given in Table 1.

### Example 2

A dicing tape was obtained in the same manner as in Example 1 except that the amount of epoxy group-containing compound blended was changed to 20 parts by mass. The results are given in Table 1.

### Example 3

A dicing tape was obtained in the same manner as in Example 1 except that the following energy ray-curable polymer was used as an energy ray-curable adhesive component and that 3.25 parts by mass of photopolymerization initiator (Irgacure (registered trade name) 184 produced by Ciba Specialty Chemicals Corporation) was blended. The results are given in Table 1.

The above energy ray-curable polymer was obtained by reacting an acrylic polymer (butyl acrylate/hydroxyethyl acrylate=85/15 (mass ratio), weight average molecular weight=about 84×10⁴) with 80% equivalent of methacryloyloxyethyl acrylate (16 parts by mass per 100 parts by mass of the acrylic polymer).

### Example 4

A dicing tape was obtained in the same manner as in Example 3 except that 20 parts by mass of epoxy group-containing compound (Epikote (registered trade name) 828, molecular weight: 370, produced by Japan Epoxy Resin Co., Ltd.) was used as the epoxy group-containing compound. The results are given in Table 1.

### Example 5

A dicing tape was obtained in the same manner as in Example 3 except that 20 parts by mass of epoxy group-containing compound (Epikote (registered trade name) 806, molecular weight: about 330, produced by Japan Epoxy Resin Co., Ltd.) was used as the epoxy group-containing compound. The results are given in Table 1.

### Comparative Example 1

Dicing tapes were obtained in the same manner as in Examples 1 and 2 except that no epoxy group-containing compound was used. The results are given in Table 1.

### Comparative Example 2

Dicing tapes were obtained in the same manner as in Examples 3, 4 and 5 except that no epoxy group-containing compound was used. The results are given in Table 1.

TABLE 1

| | | pickup time (s) | | pickup strength (N) | |
|---|---|---|---|---|---|
| | | immediately | 7 days | immediately | 7 days |
| | epoxy | after | after | after | after |
| | index | grinding | grinding | grinding | grinding |
| Example 1 | 0.205 | 1.21 | 0.78 | 5.98 | 4.75 |
| Example 2 | 0.375 | 1.06 | 0.86 | 5.73 | 5.04 |
| Example 3 | 0.205 | 1.39 | 1.02 | 6.14 | 5.13 |
| Example 4 | 0.880 | 1.42 | 1.04 | 6.09 | 5.04 |
| Example 5 | 0.989 | 1.38 | 0.99 | 5.89 | 4.70 |
| Comp. Ex. 1 | 0.000 | 2.02 | 1.27 | 7.80 | 6.02 |
| Comp. Ex. 2 | 0.000 | 1.66 | 1.05 | 7.07 | 5.20 |

As apparent from Table 1, the pickup performance of the Examples exhibited immediately after the grinding is equivalent or superior to that of the Comparative Examples using no epoxy group-containing compound exhibited 7 days after the grinding. Therefore, in the use of the dicing tapes of the Examples, the pickup operation can be performed without any problem even when they are attached immediately after the grinding of the reverse side of the wafer.

### INDUSTRIAL APPLICABILITY

In the present invention, as the dicing tape having an adhesive layer of special composition is employed, any excessive adhesion of the adhesive layer to the wafer surface immediately after the grinding of the reverse side can be avoided, thereby making it feasible to securely carry out the chip pickup after the dicing.

1. A dicing tape comprising a base material and, undetachably laminated thereon, an adhesive layer that comprises an epoxy group-containing compound being free and an adhesive component but does not contain any hardener for epoxy resins.

2. The dicing tape according to claim 1, wherein the base material on its side of the adhesive layer has a surface tension of 45 mN/m or greater.

3. The dicing tape according to claim 1, wherein the adhesive component is energy ray-curable.

4. The dicing tape according to claim 2, wherein the adhesive component is energy ray-curable.

5. A process for manufacturing a semiconductor device, comprising the steps of:
grinding the reverse side of a semiconductor wafer provided on its obverse side with a circuit,
attaching the dicing tape of claim 1 to the reverse side of the semiconductor wafer and dicing the semiconductor wafer into semiconductor chips, and
picking up the semiconductor chips.

6. The process for manufacturing a semiconductor device according to claim 5, wherein the base material on its side of the adhesive layer has a surface tension of 45 mN/m or greater.

7. The process for manufacturing a semiconductor device according to claim 5, wherein the adhesive component is energy ray-curable.

8. The process for manufacturing a semiconductor device according to claim 6, wherein the adhesive component is energy ray-curable.
